(19) United States
(12) Patent Application Publication
(10) Pub. No.: US 2026/0253836 A1
(43) Pub. Date: Aug. 27, 2026

(54) MULTI-CHARGED PARTICLE BEAM IRRADIATION APPARATUS AND ALIGNMENT METHOD

(71) Applicant: NuFlare Technology, Inc., Yokohama-shi (JP)

(72) Inventor: Taku YAMADA, Ayase-shi (JP)

(73) Assignee: NuFlare Technology, Inc., Yokohama-shi (JP)

(21) Appl. No.: 19/382,641

(22) Filed: Nov. 7, 2025

(30) Foreign Application Priority Data
Feb. 25, 2025 (JP) 2025-028133

(51) Int. Cl. H01J 37/304; H01J 37/04; H01J 37/317

(52) U.S. Cl. CPC H01J 37/3045; H01J 37/045; H01J 37/3177; H01J 2237/0437; H01J 2237/24535

(57) ABSTRACT

In one embodiment, an alignment method is for aligning a first aperture array substrate and a second aperture array substrate disposed sequentially. The first aperture array substrate has a plurality of first openings, and the second aperture array substrate has a plurality of second openings. The alignment method includes irradiating a plurality of first openings with a charged particle beam to form a first beam array, measuring, by the first beam array, at least one of an amount of charged particles irradiating the second aperture array substrate, an amount of charged particles irradiating and reflected from or generated at the second aperture array substrate, and an amount of charged particles irradiating the second aperture array substrate and passing through the plurality of second openings, and adjusting a relative position between the first beam array and the plurality of second openings based on a measured charged particle amount.

### CROSS REFERENCE TO RELATED APPLICATION

This application is based upon and claims benefit of priority from the Japanese Patent Application No. 2025-28133, filed on February 25, 2025, the entire contents of which are incorporated herein by reference.

### FIELD

The present invention relates to a multi-charged particle beam irradiation apparatus and an alignment method.

### BACKGROUND

As LSI circuits are increasing in density, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed on quartz is transferred to a wafer in a reduced manner by using a reduced-projection exposure apparatus. The high-precision original pattern is written by using an electron-beam writing apparatus, in which a so-called electron-beam lithography technique is employed.

A writing apparatus using multiple beams enables irradiation with a large number of beams at once as compared with writing with a single electron beam, and thereby significantly improve throughput. Examples of such multi-beam writing apparatuses include a multi-beam writing apparatus using a blanking aperture array substrate (blanking plate). In such a multi-beam writing apparatus, for example, an electron beam emitted from an electron source passes through a shaping aperture array substrate having multiple apertures, thus forming multiple beams (multiple electron beams). The multiple beams pass through respective blankers corresponding to them in a blanking aperture array substrate. The blanking aperture array substrate includes pairs of electrodes for individually deflecting the beams, and has an aperture for beam passage between each pair of electrodes. One of the paired electrodes (blanker) is held at ground potential, and the other electrode is switched between the ground potential and a potential other than the ground potential, thus achieving blanking deflection of an electron beam that is to pass through the blanker. An electron beam deflected by the blanker is blocked and an electron beam that is not deflected is applied to a sample.

In the multi-beam writing apparatus, the openings of the shaping aperture array substrate and the openings of the blanking aperture array substrate need to be aligned so that multiple beams formed in the shaping aperture array substrate pass through respective openings of the blanking aperture array substrate. Conventionally, a transmitted current has been detected to perform alignment by a current detector provided in the stage on which a sample is placed while translating and θ-rotating either one of the shaping aperture array substrate or the blanking aperture array substrate. When the positions of two aperture array substrates are aligned, the transmitted current detected is maximized.

In order to reduce the heat load of the shaping aperture array substrate, a pre-aperture array substrate having a plurality of openings may be provided above the shaping aperture array substrate. When three aperture array substrates, that is, the pre-aperture array substrate, the shaping aperture array substrate and the blanking aperture array substrate are installed, even when one of the aperture array substrates is translated or θ-rotated properly, the ratio of the beam passing through the openings of the three aperture array substrates is extremely low, and the beam hardly reaches the stage. Therefore, a transmitted current cannot be detected by a current detector, thus alignment of the aperture array substrates has been difficult.

### BRIEF DESCRIPTION OF THE DRAWINGS

FIG. 1 is a schematic view of a writing apparatus according to an embodiment of the present invention.

FIG. 2 is a flowchart for explaining an alignment method for an aperture array substrate according to the embodiment.

FIG. 3 is a graph showing an example of a result of measurement of an amount of reflected electrons.

FIG. 4 is a graph showing an example of a result of measurement of a transmitted current amount.

FIGS. 5A to 5C are plan views of a detector.

FIG. 6 is a schematic view of a writing apparatus according to a modification.

### DETAILED DESCRIPTION

In one embodiment, a multi-charged particle beam irradiation apparatus includes a charged particle source configured to emit a charged particle beam, a plurality of lenses configured to adjust a trajectory of the charged particle beam, a first aperture array substrate configured to receive irradiation of the charged particle beam to form a first beam array, the first aperture array substrate having a plurality of first openings, a second aperture array substrate disposed downstream of the first aperture array substrate in a beam traveling direction, the second aperture array substrate having a plurality of second openings, a detector provided upstream of a final-stage lens among the plurality of lenses in a traveling direction of the charged particle beam, the detector being configured to measure, by the first beam array, at least one of an amount of charged particles irradiating the second aperture array substrate, an amount of charged particles irradiating and reflected from or generated at the second aperture array substrate, and an amount of charged particles irradiating the second aperture array substrate and passing through the plurality of second openings, and a controller configured to adjust a relative position between the first beam array and the plurality of second openings based on a measurement result obtained by the detector.

In the following embodiments, a configuration using an electron beam as an example of a charged particle beam will be described. However, the charged particle beam is not limited to an electron beam, and may also be a beam using charged particles such as an ion beam.

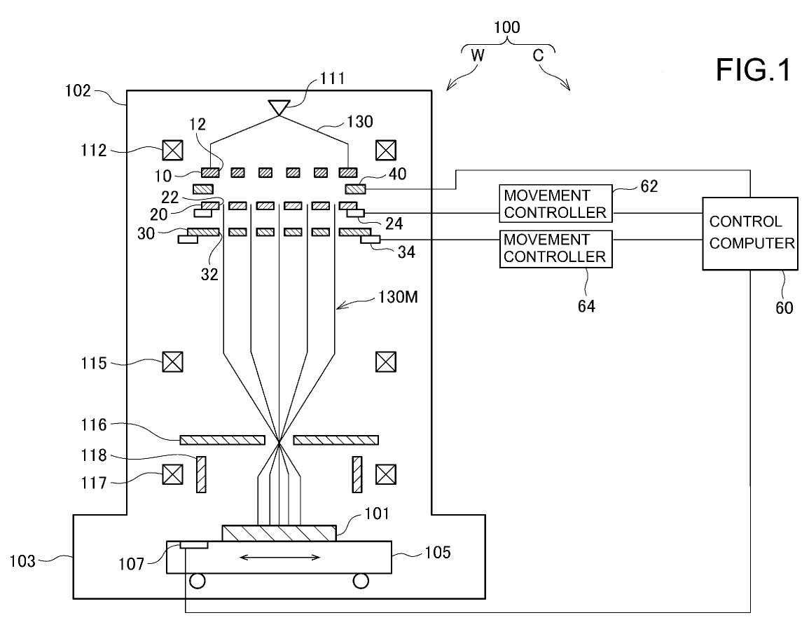

FIG. 1 is a schematic view of a writing apparatus according to the embodiment. A writing apparatus 100 illustrated in FIG. 1 is an example of a multi-charged particle beam writing apparatus. The writing apparatus 100 includes a controller C and a writer W.

The controller C includes a control computer 60, and movement controllers 62 and 64. The writer W includes an electron optical column 102 and a writing chamber 103.

In the electron optical column 102, an electron source 111, an illumination lens 112, a pre-aperture array substrate 10, a shaping aperture array substrate 20, a movable stage 24, a blanking aperture array substrate 30, a movable stage 34, a detector 40, a reduction lens 115, a limiting aperture member 116, an objective lens 117 and a deflector 118 are disposed.

The three aperture array substrates, that is, the pre-aperture array substrate 10, the shaping aperture array substrate 20 and the blanking aperture array 30 are disposed sequentially from an upstream side of the beam traveling direction. The detector 40 is disposed between the pre-aperture array substrate 10 and the shaping aperture array substrate 20.

An XY stage 105 is disposed in the writing chamber 103. A substrate 101 as a writing target is disposed on the XY stage 105. The substrate 101 is e.g., a mask blank coated with a resist. In addition, the XY stage 105 is provided with a current detector 107 that detects the beam current. The current detector 107 is e.g., a Faraday cup. The result of detection by the current detector 107 is output to the control computer 60.

A plurality of openings 12 are formed in the pre-aperture array substrate 10. For example, the openings 12 in vertical m columns × horizontal n rows (m, n ≥ 2) are formed with a predetermined arrangement pitch. The shape of each opening 12 is e.g., rectangular or circular. The pre-aperture array substrate 10 is provided above the shaping aperture array substrate 20 to reduce the heat load of the shaping aperture array substrate 20.

In the shaping aperture array substrate 20, openings 22 are formed corresponding to the arrangement positions of the openings 12 of the pre-aperture array substrate 10. The shape of each opening 22 is e.g., rectangular or circular. The shaping aperture array substrate 20 is placed on the movable stage 24. The operation of the movable stage 24 is controlled by the movement controller 62. The shaping aperture array substrate 20 is made movable (XY) and rotatable (θ) by the movable stage 24 within a plane (for example, within a horizontal plane) perpendicular to the beam traveling direction.

An electron beam 130 emitted from the electron source 111 illuminates the pre-aperture array substrate 10 by the illumination lens 112. The electron beam 130 passes through the plurality of openings 12 of the pre-aperture array substrate 10 and the plurality of openings 22 of the shaping aperture array substrate 20, thereby forming multiple electron beams (multi-beam) 130M.

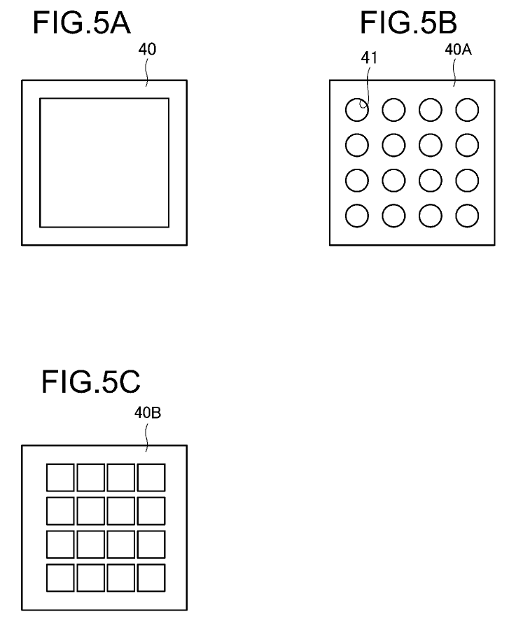

The detector 40 disposed between the pre-aperture array substrate 10 and the shaping aperture array substrate 20 is a frame in a picture frame shape (see FIG. 5A), and the beam passing through the pre-aperture array substrate 10 passes through an opening, i.e., an inner region of the frame. The opening of the detector 40 is larger in size than the beam array which passes through the pre-aperture array substrate 10, and reaches the shaping aperture array substrate 20. The detector 40 detects reflected electrons (including secondary electrons) from the shaping aperture array substrate 20. For example, the lower surface side of the detector 40 serves as a detection surface. The amount of the reflected electrons detected by the detector 40 is output to the control computer 60.

The blanking aperture array substrate 30 is provided below the shaping aperture array substrate 20, and openings 32 are formed corresponding to the arrangement positions of the openings 22 of the shaping aperture array substrate 20. The shape of each opening 32 is e.g., rectangular or circular. In the vicinity of each opening 32, a blanker consisting of a set of two electrodes forming a pair is disposed. The two electrodes are disposed opposite to each other so as to interpose the opening 32 therebetween. One of the electrodes is fixed to the ground electric potential, and the other one of the electrodes is switched between the ground electric potential and another electric potential.

The blanking aperture array substrate 30 is placed on the movable stage 34. The operation of the movable stage 34 is controlled by the movement controller 64. The blanking aperture array substrate 30 is made movable (XY) and rotatable (θ) by the movable stage 34 within a plane perpendicular to the beam traveling (propagation) direction.

The multi-beam 130M passes through between electrodes and the opening 32 of each of corresponding blankers of the blanking aperture array substrate 30.

The electron beam passing through the opening 32 is independently controlled for each beam in a beam-ON or beam-OFF state by the voltage applied to a corresponding blanker. In a beam-ON state, the opposed electrodes of a blanker are controlled at the same potential, and the blanker does not deflect the beam. In a beam-OFF state, the opposed electrodes of a blanker are controlled at different potentials, and the blanker deflects the beam. In this manner, multiple blankers perform blanking deflection on corresponding beams in the multi-beam 130M which has passed through the plurality of openings 22 of the shaping aperture array substrate 20.

The multi-beam 130M which has passed through the blanking aperture array substrate 30 is reduced by the reduction lens 115, and ideally passes through the same point on the limiting aperture member 116 with all beams in an ON state. The trajectory of the beam is adjusted by an alignment coil which is not illustrated so that the above-mentioned point is located in the hole of the limiting aperture member 116. Each beam controlled in a beam-OFF state is deflected by a blanker of the blanking aperture array substrate 30, and passes through a trajectory deviated from the hole of the limiting aperture member 116, thus is blocked by the limiting aperture member 116. In contrast, each beam controlled in a beam-ON state is not deflected by a blanker, thus passes through the hole of the limiting aperture member 116. In this manner, ON/OFF of the beam is controlled by the blanking control of the blanking aperture array substrate 30.

The multi-beam which has passed through the limiting aperture member 116 is focused by the objective lens 117, and is projected on the substrate 101 with a desired reduction ratio. The entire multi-beam is collectively deflected by the deflector 118 in the same direction, and directed to respective irradiation positions on the substrate 101. When the XY stage 105 is moved continuously, the irradiation position of the beam is controlled by the deflector 118 so that the irradiation position follows the movement of the XY stage 105.

In order for the beam to reach the substrate 101, it is necessary to match (align) the positions of the openings 12 of the pre-aperture array substrate 10, the openings 22 of the shaping aperture array substrate 20, and the openings 32 of the blanking aperture array substrate 30.

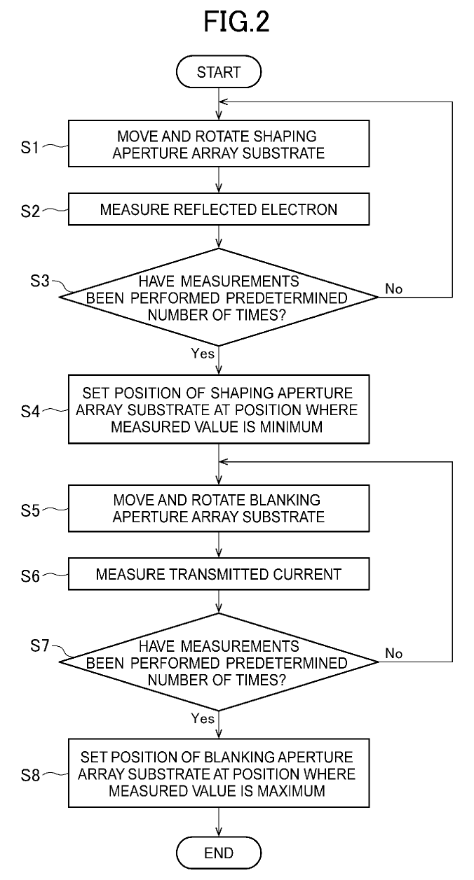

An alignment method for the openings of the aperture array substrates will be described based on the flowchart illustrated in FIG. 2.

An electron beam is emitted from the electron source 111, and the position of the shaping aperture array substrate 20 is displaced by a predetermined amount (step S1). Here, to displace the position of the shaping aperture array substrate 20 includes at least one of movement in X direction, movement in Y direction, and rotation within a horizontal plane. The control computer 60 outputs a control signal to the movement controller 62. The movement controller 62 drives the movable stage 24 based on the control signal.

Part of the electron beam (first beam array) which has passed through the pre-aperture array substrate 10 collides with the shaping aperture array substrate 20. The detector 40 measures the amount of reflected electrons (step S2). The measured reflected electrons include generated secondary electrons.

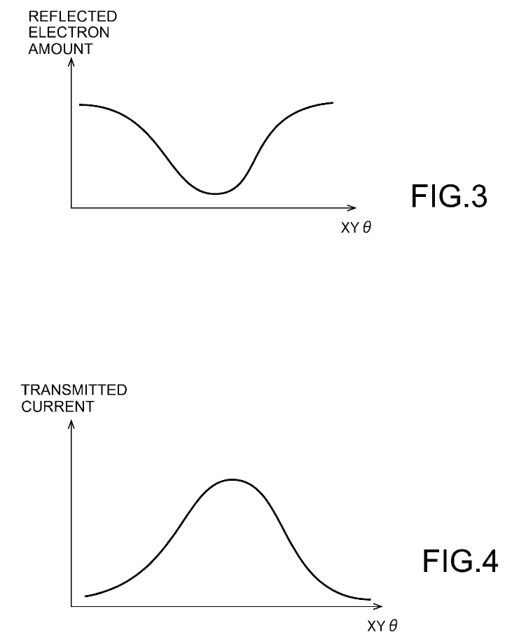

Displacement of the position of the shaping aperture array substrate 20 and measurement of reflected electrons are repeated multiple times (step S3). Thus, a relationship between the position in XY direction and angle (θ) of the shaping aperture array substrate 20, and the amount of reflected electrons as illustrated in FIG. 3 is obtained. When the amount of reflected electrons is a local minimum value, the electron beam (second beam array) which passes through the shaping aperture array substrate 20 has the largest amount. In other words, the position and angle that achieve a local minimum of the amount of reflected electrons can be regarded as an aligned state of the openings 12 of the pre-aperture array substrate 10 and the openings 22 of the shaping aperture array substrate 20.

The control computer 60 obtains a result of measurement by the detector 40, detects the position and angle that achieve a local minimum of the amount of reflected electrons, and outputs a control signal to the movement controller 62 so that the shaping aperture array substrate 20 is set to the detected position and angle (step S4).

Next, the position of the blanking aperture array substrate 30 is displaced by a predetermined amount (step S5). Here, to displace the position of the blanking aperture array substrate 30 includes at least one of movement in X direction, movement in Y direction, and rotation within a horizontal plane. The control computer 60 outputs a control signal to the movement controller 64. The movement controller 64 drives the movable stage 34 based on the control signal.

The beam current which has transmitted (passed) through the blanking aperture array substrate 30 is measured using the current detector 107 (step S6).

Displacement of the blanking aperture array substrate 30 and measurement of the transmitted current are repeated multiple times (step S7). Thus, a relationship between the position in XY direction and angle (θ) of the blanking aperture array substrate 30, and the transmitted current amount as illustrated in FIG. 4 is obtained. When the transmitted current amount is a local maximum value, this can be regarded as an aligned state of the openings 22 of the shaping aperture array substrate 20 and the openings 32 of the blanking aperture array substrate 30.

The control computer 60 obtains a result of measurement by the current detector 107, detects the position and angle that achieve a maximum of the transmitted current amount, and outputs a control signal to the movement controller 64 so that the blanking aperture array substrate 30 is set to the detected position and angle (step S8).

Thus, the openings 12 of the pre-aperture array substrate 10, the openings 22 of the shaping aperture array substrate 20, and the openings 32 of the blanking aperture array substrate 30 can be aligned.

As the material for the shaping aperture array substrate 20, silicon, molybdenum, tantalum, tungsten and the like may be used. In order to facilitate detection of reflected electrons by the detector 40, it is preferable to form a film of a material on the surface of the shaping aperture array substrate 20, the material with an atomic number greater than that of the material for the shaping aperture array substrate 20, such as gold and platinum.

The shape of the detector 40 is not limited to the frame as illustrated in FIG. 5A. For example, as illustrated in FIG. 5B, a detector 40A may be used, which has a plurality of openings 41 aligned with the arrangement positions of the openings 12 of the pre-aperture array substrate 10 and the openings 22 of the shaping aperture array substrate 20. In order to allow the detector 40A to be mechanically aligned with the pre-aperture array substrate 10 and the shaping aperture array substrate 20, the size of the openings 41 is sufficiently larger than the openings 12, 22.

A mesh-shaped detector 40B as illustrated in FIG. 5C may be used. Each opening portion of the detector 40B may correspond to one opening 12, 22, or may include two or more openings 12, 22.

In the above embodiment, the configuration has been described in which when the pre-aperture array substrate 10 and the shaping aperture array substrate 20 are aligned, the position of the shaping aperture array substrate 20 is displaced; however, the pre-aperture array substrate 10 may be placed on the movable stage, and reflected electrons from the shaping aperture array substrate 20 may be detected by the detector 40 while displacing the position of the pre-aperture array substrate 10.

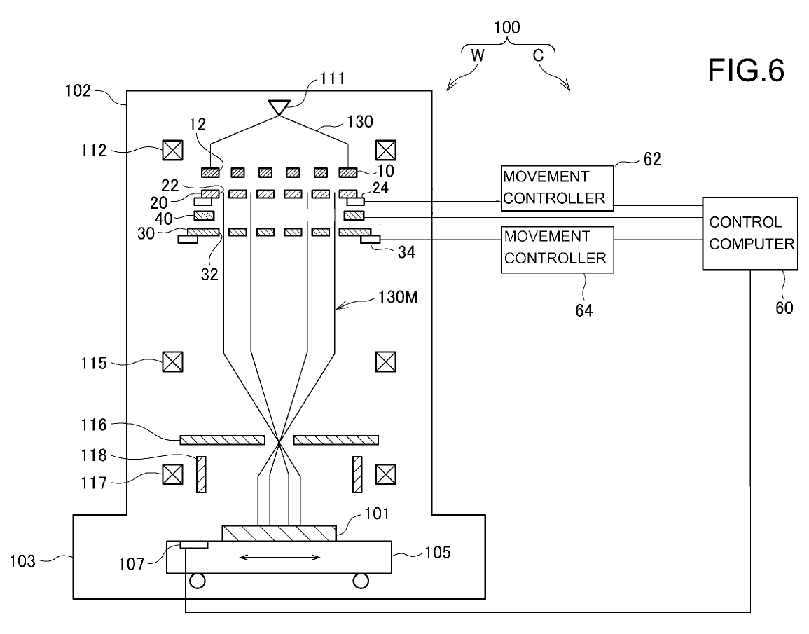

In the above embodiment, the configuration has been described in which the detector 40 is placed between the pre-aperture array substrate 10 and the shaping aperture array substrate 20; however, as illustrated in FIG. 6, the detector 40 may be placed between the shaping aperture array substrate 20 and the blanking aperture array substrate 30. In this case, the upper surface side of the detector 40 serves as a detection surface, and the detector 40 detects an electron which has passed through the shaping aperture array substrate 20.

The amount of electrons which have passed through the shaping aperture array substrate 20 is measured while shifting the position of the pre-aperture array substrate 10 or the shaping aperture array substrate 20. When the measured value is a local maximum, this can be regarded as an aligned state of the openings 12 of the pre-aperture array substrate 10 and the openings 22 of the shaping aperture array substrate 20.

The detector 40 may be omitted, and the shaping aperture array substrate 20 or the blanking aperture array substrate 30 may be used as a detector. In this case, it is preferable to form a film of a material on the surfaces of the shaping aperture array substrate 20, and the blanking aperture array substrate 30 so that electrical conductivity is provided to the surfaces, the material with a smaller atomic number, such as carbon, aluminum, titanium, which reduces the amount of reflected electrons.

When the shaping aperture array substrate 20 is used as a detector, the amount of electrons which collide with the shaping aperture array substrate 20 is measured while displacing the position of the pre-aperture array substrate 10 or the shaping aperture array substrate 20. The smaller the measured value, the more beams pass through the openings 22 without colliding with the shaping aperture array substrate 20. When the measured value is a local minimum, this can be regarded as an aligned state of the openings 12 of the pre-aperture array substrate 10 and the openings 22 of the shaping aperture array substrate 20.

When the blanking aperture array substrate 30 is used as a detector, the amount of electrons which collide with the blanking aperture array substrate 30 is measured while displacing the position of the pre-aperture array substrate 10 or the shaping aperture array substrate 20. The larger the measured value, the more beams pass through the openings 22 without colliding with the shaping aperture array substrate 20. When the measured value is a local maximum, this can be regarded as an aligned state of the openings 12 of the pre-aperture array substrate 10 and the openings 22 of the shaping aperture array substrate 20.

Note that the position of the detector 40 is not limited to the upstream side of the blanking aperture array substrate 30 in a traveling direction of the beam. It is sufficient that the detector 40 can make measurement before the beam reaches a substrate surface, and can be disposed upstream of the objective lens 117 that is the final stage lens of a plurality of lenses that adjust the beam trajectory. For example, blanking may be performed on all beams by the blanking aperture array substrate 30, and the amount of electrons colliding with the limiting aperture member 116 may be measured.

The position of the adjusted openings is not necessarily limited to the one which gives a local minimum value or a local maximum value of the measured amount (amount of charged particles) of electrons, and may be adjusted so that the measured value is in the vicinity of a local minimum value or a local maximum value.

In the above embodiment, a multi-electron beam may be emitted from a photocathode. Multiple excitation lights are generated from an array light source having multiple light sources. The multiple excitation lights illuminate a multi-lens array. The multi-lens array further divides the multiple excitation lights into multiple lights, and the multiple divided light are focused, and the focus position of each light is aligned with the height position of the surface of the photocathode. The photocathode allows multiple lights to be incident on its surface, and a multi-electron beam to be emitted from its back surface. Instead of the pre-aperture array substrate 10, an aperture array substrate is provided, which draws, and accelerates the electrons emitted from the photocathode. The accelerated multi-electron beam travels to the shaping aperture array substrate 20.

In the above embodiment, the configuration has been described in which at least one of two aperture array substrates to be aligned is placed on the movable stage, and moved or rotated; however, instead of the movable stage, a deflector or an electric field/magnetic field lens which moves or rotates the beam array may be provided between the two aperture array substrates.

In the above embodiment, a multi-charged particle beam writing apparatus has been described as an example; however, the present embodiment can also be applied to other multi-charged particle beam irradiation apparatuses, such as a multi-charged particle beam inspection apparatus.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi-charged particle beam irradiation apparatus comprising:
a charged particle source configured to emit a charged particle beam;
a plurality of lenses configured to adjust a trajectory of the charged particle beam;
a first aperture array substrate configured to receive irradiation of the charged particle beam to form a first beam array, the first aperture array substrate having a plurality of first openings;
a second aperture array substrate disposed downstream of the first aperture array substrate in a beam traveling direction, the second aperture array substrate having a plurality of second openings;
a detector provided upstream of a final-stage lens among the plurality of lenses in a traveling direction of the charged particle beam, the detector being configured to measure, by the first beam array, at least one of an amount of charged particles irradiating the second aperture array substrate, an amount of charged particles irradiating and reflected from or generated at the second aperture array substrate, and an amount of charged particles irradiating the second aperture array substrate and passing through the plurality of second openings; and
a controller configured to adjust a relative position between the first beam array and the plurality of second openings based on a measurement result obtained by the detector.

2. The multi-charged particle beam irradiation apparatus according to claim 1, further comprising
a movable stage on which the first aperture array substrate or the second aperture array substrate is mounted, or a deflector or a lens that is each disposed between the first aperture array substrate and the second aperture array substrate, and that moves or rotates the first beam array,
wherein the controller adjusts the relative position by using at least one of the movable stage, the deflector, and the lens.

3. The multi-charged particle beam irradiation apparatus according to claim 1, further comprising
a third aperture array substrate disposed downstream of the second aperture array substrate in a beam traveling direction, the third aperture array substrate having a plurality of third openings,
wherein the detector measures, by a second beam array that has passed through the plurality of second openings, an amount of charged particles emitted to the third aperture array substrate, or an amount of charged particles irradiating and reflected from or generated at the third aperture array substrate.

4. The multi-charged particle beam irradiation apparatus according to claim 3, further comprising:
a current detector configured to measure a beam current of a beam that has transmitted through the third aperture array substrate,
wherein the controller adjusts a relative position between the plurality of second openings and the plurality of third openings so that the beam current reaches a local maximum value.

5. The multi-charged particle beam irradiation apparatus according to claim 1,
wherein a plurality of fourth openings are formed in the detector, and a size of the fourth openings is larger than sizes of the first openings and the second openings.

6. The multi-charged particle beam irradiation apparatus according to claim 1,
wherein the detector is disposed between the first aperture array substrate and the second aperture array substrate to measure an amount of reflected charged particles from the second aperture array substrate, and
the controller adjusts the relative position between the first beam array and the plurality of second openings so that the measured amount of reflected charged particles reaches a local minimum value.

7. The multi-charged particle beam irradiation apparatus according to claim 6,
wherein a material having an atomic number greater than an atomic number of a material of the second aperture array substrate is formed as a film on a surface of the second aperture array substrate.

8. An alignment method for aligning a first aperture array substrate and a second aperture array substrate disposed sequentially, the first aperture array substrate having a plurality of first openings, the second aperture array substrate having a plurality of second openings, the alignment method comprising:
irradiating a plurality of first openings with a charged particle beam to form a first beam array;
measuring, by the first beam array, at least one of an amount of charged particles irradiating the second aperture array substrate, an amount of charged particles irradiating and reflected from or generated at the second aperture array substrate, and an amount of charged particles irradiating the second aperture array substrate and passing through the plurality of second openings; and
adjusting a relative position between the first beam array and the plurality of second openings based on a measured charged particle amount.

9. The alignment method according to claim 8,
wherein the relative position is adjusted so that the measured charged particle amount reaches a local minimum value or a local maximum value.

10. The alignment method according to claim 8,
wherein a third aperture array substrate having a plurality of third openings is irradiated with a second beam array that has passed through the plurality of second openings, and
a relative position between the plurality of second openings and the plurality of third openings is adjusted so that a beam current of a beam which has transmitted through the third aperture array substrate reaches a local maximum value.
